(19) United States
(12) Patent Application Publication
(10) Pub. No.: US 2010/0260223 A1
(43) Pub. Date: Oct. 14, 2010

(54) Quantum dot laser diode and method of fabricating the same

(76) Inventors: Jin Soo Kim, Seo-gu (KR); Jin Hong Lee, Yuseong-gu (KR); Sung Ui Hong, Chung-gu (KR); Ho Sang Kwack, Cheonan-si (KR); Byung Seok Choi, Seo-gu (KR); Dae Kon Oh, Yuseong-gu (KR)

Correspondence Address: LADAS & PARRY LLP, 224 SOUTH MICHIGAN AVENUE, SUITE 1600, CHICAGO, IL, 60604, US

(21) Appl. No.: 11/633,201

(22) Filed: Dec. 4, 2006

(30) Foreign Application Priority Data
Dec. 6, 2005 (KR) 10-2005-0118136
Jun. 22, 2006 (KR) 10-2006-0056212

(51) Int. Cl. H01S 5/343; H01L 33/02

(52) U.S. Cl. 372/45.01; 438/47; 977/774; 257/E33.005

(57) ABSTRACT

A quantum dot laser diode and a method of fabricating the same are provided. The quantum dot laser diode includes: a first clad layer formed on an InP substrate; a first lattice-matched layer formed on the first clad layer; an active layer formed on the first lattice-matched layer, and including at least one quantum dot layer formed of an InAlAs quantum dot or an InGaPAs quantum dot which is grown by an alternate growth method; a second lattice-matched layer formed on the active layer; a second clad layer formed on the second lattice-matched layer, and an ohmic contact layer formed on the second clad layer.

### CROSS-REFERENCE TO RELATED APPLICATION

This application claims priority to and the benefit of Korean Patent Application Nos. 2005-118136, filed Dec. 6, 2005, and 2006-56212, filed Jun. 22, 2006, the disclosures of which are incorporated herein by reference in their entirety.

### BACKGROUND

1. Field of the Invention

The present invention relates to a quantum dot laser diode and a method of fabricating the same, and more particularly, to a quantum dot laser diode and a method of fabricating the same which use quantum dots formed by an alternate growth method as an active layer.

2. Discussion of Related Art

Recently, there has been considerable research into a Stranski-Krastanow growth method that forms self-assembled quantum dots using a strain-relaxation process of a lattice-mismatched layer without a separate lithography process. Further, application of self-assembled quantum dots formed by the Stranski-Krastanow growth method to optical devices has been studied from various angles.

For example, application of self-assembled quantum dots in optical communication using wavelength regions of 1.3 μm and 1.55 μm is being actively researched. Here, in the 1.3 μm wavelength region, In(Ga)As quantum dots may be used. The In(Ga)As quantum dots may be easily grown by self-assembly on a GaAs substrate. In this manner, many studies on optical devices such as a laser diode using In(Ga)As quantum dots grown by self-assembly as an active layer are announced.

When In(Ga)As quantum dots are formed on a GaAs substrate to use the In(Ga)As quantum dots in a wavelength region of 1.55 μm, there is a limit to implementation of the 1.55 μm wavelength region due to effects of size of the In(Ga)As quantum dots and stress of a peripheral material. Accordingly, formation of In(Ga)As quantum dots utilized in the 1.55 μm wavelength region on an InP substrate is being actively researched.

However, an InP substrate has less lattice-mismatch with a material layer forming the quantum dots than the GaAs substrate and reacts with peripheral materials. Thus, it has difficulty in forming good quantum dots by self-assembly. Moreover, since In(Ga)As quantum dots formed on an InP substrate have an asymmetrical shape, or a very wide full-width at half-maximum (FWHM) of a photoluminescence (PL) peak and a weak intensity of the PL peak due to poor uniformity, when used for an active layer of an optical device, the efficiency of the optical device may decrease.

### SUMMARY OF THE INVENTION

The present invention is directed to a quantum dot laser diode and a method of fabricating the same in which quantum dots are formed using an alternate growth method, thereby improving uniformity, increasing full-width at half-maximum (FWHM) of a PL peak, and increasing PL intensity, which in turn enhances device characteristics.

According to one aspect of the present invention, a quantum dot laser diode comprises: a first clad layer formed on an InP substrate; a first lattice-matched layer formed on the first clad layer; an active layer formed on the first lattice-matched layer, and including at least one quantum dot layer formed of an In(Ga, Al)As quantum dot or an In(Ga, Al, P)As quantum dot which is grown by an alternate growth method; a second lattice-matched layer formed on the active layer; a second clad layer formed on the second lattice-matched layer; and an ohmic contact layer formed on the second clad layer.

In the case of forming the multiple quantum dot layers, a barrier layer may be further included between the quantum dot layers. The In(Ga, Al)As quantum dot may be formed by sequentially, alternately depositing an In(Ga)As material layer and an InAl(Ga)As material layer, which are relatively more lattice-mismatched. Alternatively, the In(Ga, Al, P)As quantum dot may be formed by sequentially, alternately depositing an In(Ga)As material layer and an In(Ga, Al, As)P material layer, which are relatively more lattice-mismatched.

The In(Ga)As and InAl(Ga)As material layers, or the In(Ga)As and In(Ga, Al, As)P material layers, which may be used for the alternating deposition, may each have a thickness ranging from 1 monolayer to 10 monolayers. The In(Ga)As and InAl(Ga)As material layers, or the In(Ga)As and In(Ga, Al, As)P material layers, which are used for the alternating deposition, may have an alternating deposition period of 10 to 100.

The first lattice-matched layer, the second lattice-matched layer and the barrier layer may be formed in a hetero-junction structure (SCH structure) formed of InAl(Ga)As, In(Ga, Al, As)P or a combination thereof. In such an SCH structure, a waveguide may have a step index (SPIN) structure, and therein a quantum well may be inserted so as to symmetrically or asymmetrically surround the quantum dots (DWELLs). Alternatively, in the SCH structure, the waveguide may have a graded index (GRIN) structure, and therein a quantum well may be inserted so as to symmetrically or asymmetrically surround the quantum dots.

According to another aspect of the present invention, a method of fabricating a quantum dot laser diode comprises the steps of: forming a first clad layer on an InP substrate; forming a first lattice-matched layer on the first clad layer; forming an active layer on the first lattice-matched layer, the active layer including at least one quantum dot layer formed of an In(Ga, Al)As quantum dot and an In(Ga, Al, P)As quantum dot grown by an alternating deposition method; forming a second lattice-matched layer on the active layer; forming a second clad layer on the second lattice-matched layer; and forming an ohmic contact layer on the second clad layer.

The method may further comprise the step of forming a barrier layer between the quantum dot layers, when a plurality of quantum dot layers are stacked in the step of forming the active layer. The In(Ga, Al)As quantum dot may be formed by alternately depositing an In(Ga)As material layer and InAl(Ga)As material layer in sequence, which are relatively more lattice-mismatched. Alternatively, the In(Ga, Al, P)As quantum dot may be formed by alternately depositing an In(Ga)As material layer and In(Ga, Al, As)P material layer in sequence, which are relatively more lattice-mismatched. The alternating deposition may be performed by one of metallic organic chemical vapor deposition (MOCVD), molecular beam epitaxy (MBE), and chemical beam epitaxy (CBE).

The present invention is related to Korean Patent Application No. 2005-85194 entitled “Method for Fabricating Quantum Dots by an Alternate Growth Process” filed by the present applicant. The present specification refers to parts of a method of fabricating quantum dots described in previously filed Korean Patent Application No. 2005-85194.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1A is a flowchart illustrating a procedure of fabricating a laser diode using quantum dots according to the present invention, and FIG. 1B is a flowchart showing step S140 of the procedure of FIG. 1A in detail;

FIGS. 2A to 2G are cross-sectional views of steps in the procedure of fabricating a quantum dot laser diode of FIGS. 1A and 1B;

FIG. 3A is a cross-sectional tunneling electron microscope (TEM) photograph of a quantum dot specimen (QD1) formed by a method of the present invention, and FIG. 3B is a cross-sectional TEM photograph of a quantum dot specimen (QD2) fabricated by a conventional method;

FIG. 4 shows a graph \textcircled{a} illustrating room-temperature photoluminescence characteristics of a quantum dot specimen (QD1) produced according to the present invention, and a graph \textcircled{b} illustrating room-temperature photoluminescence characteristics of a quantum dot specimen (QD2) produced according to conventional art; and

FIG. 5 shows a graph illustrating room-temperature PL characteristics according to excitement intensity of a quantum dot specimen produced by the present invention as a function of wavelength.

### DETAILED DESCRIPTION OF EXEMPLARY EMBODIMENTS

Hereinafter, exemplary embodiments of the present invention will be described in detail with reference to attached drawings.

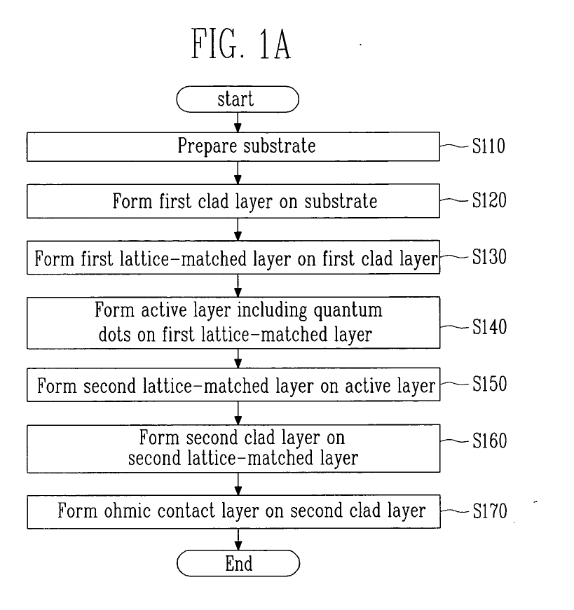

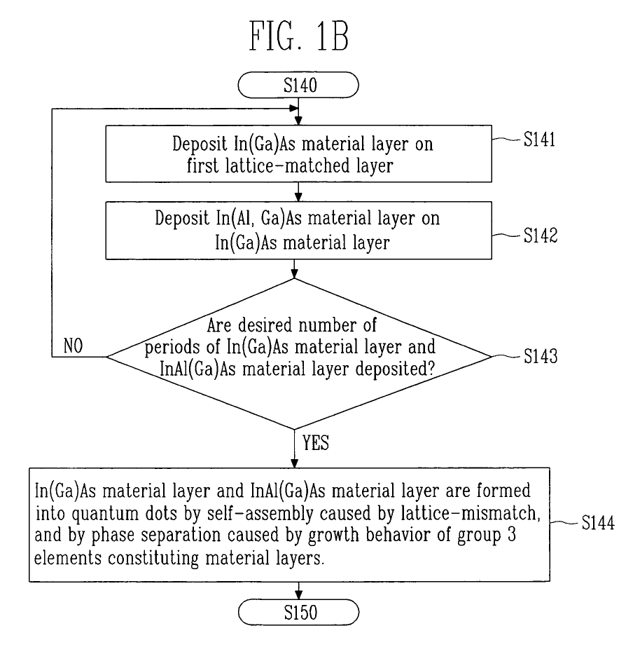

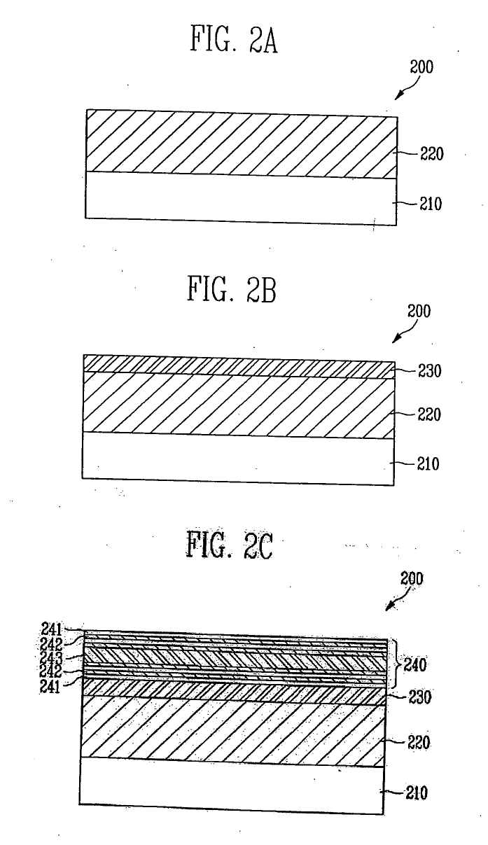

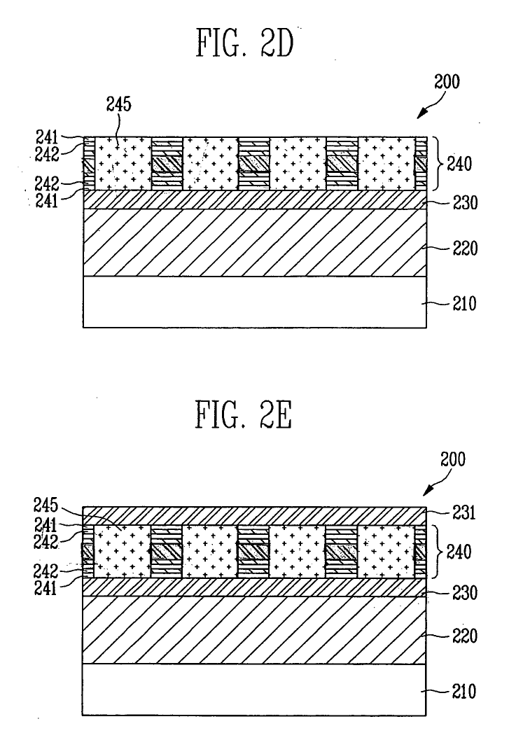

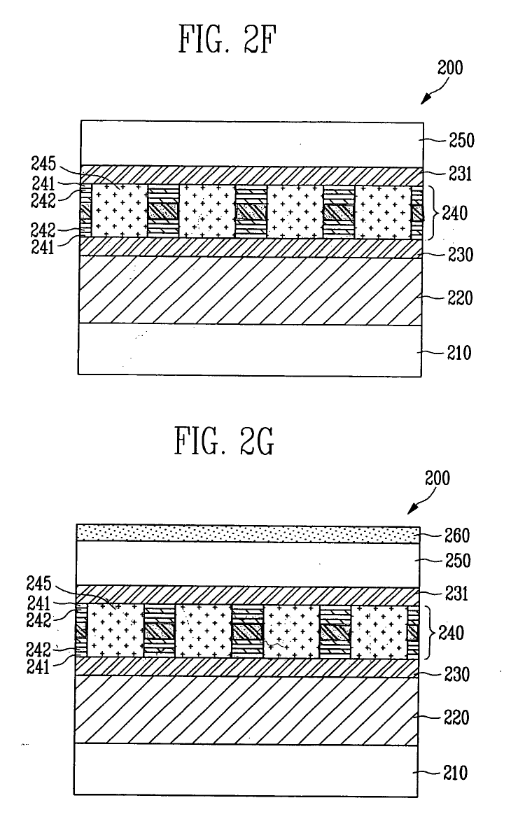

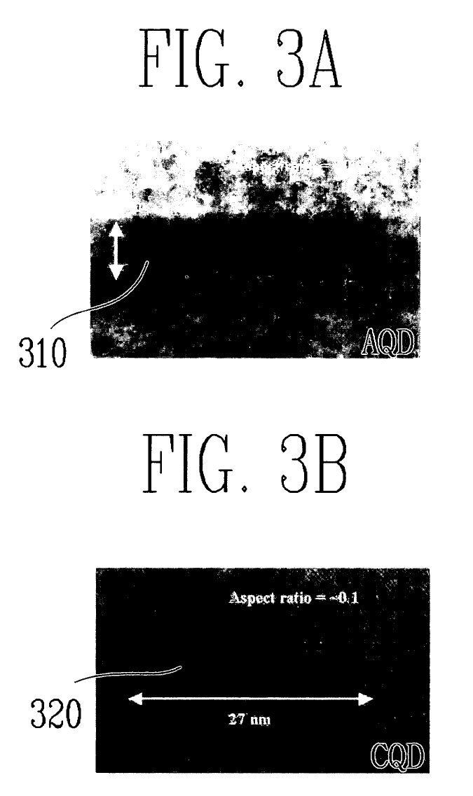

FIG. 1A is a flowchart illustrating a procedure of fabricating a laser diode using quantum dots according to the present invention, FIG. 1B is a flowchart showing step S140 of the procedure of FIG. 1A in detail, and FIGS. 2A to 2G are cross-sectional views of steps in the procedure of fabricating a quantum dot laser diode of FIGS. 1A and 1B.

Referring to FIGS. 1A and 2A, to fabricate a quantum dot laser diode 200 according to the present invention, first, a substrate 210 is prepared (S110). The substrate 210 is an InP substrate, and in its preparation, a thermal treatment process is performed in an atmosphere of P or As. A first clad layer 220 is formed on the InP substrate 210 to confine emitted light therein to prevent optical loss (S120). The first clad layer 220 may be formed of n-(p-)InAl(Ga)As or n-(p-)In(Ga, As)P. The first clad layer 220 is formed with a different conductivity type from the following second clad layer 250. For example, the first clad layer 220 is formed of n-InAl(Ga)As, and the second clad layer 250 is formed of p-InAl(Ga)As.

Referring to FIGS. 1A and 2B, a first lattice-matched layer 230 is formed on the first clad layer 220 (S130). The first lattice-matched layer 230 is formed in a hetero-junction structure (SCH structure) in which InAlGaAs, In(Ga, Al, As)P or both of them are lattice-matched to serve as a barrier layer. The first lattice-matched layer 230, the SCH structure layer, may have a waveguide which is formed in a step index (SPIN) or graded index (GRIN) structure.

Here, the first lattice-matched layer 230 may have a quantum well inserted into the SPIN SCH structure so as to symmetrically or asymmetrically surround a following quantum dot (quantum dot in a quantum well: DWELL). Alternately, the first lattice-matched layer 230 may have a quantum well inserted into the GRIN SCH structure so as to symmetrically or asymmetrically surround a following quantum dot.

Next, an active layer 240 composed of a quantum dot layer including a plurality of quantum dots 245 is formed on the first lattice-matched layer 230 (S140). To fabricate the active layer 240, referring to FIGS. 1B and 2C, an In(Ga)As material layer 241 that is more lattice-matched is deposited on the first lattice-matched layer 230 (S141). And, an In(Al, Ga)As material layer 242 is deposited on the In(Ga)As material layer 241 (S142). As shown in FIG. 2C, the In(Ga)As material layer 241 and the InAl(Ga)As material layer 242 are repeatedly, alternately deposited, and then it is determined whether deposition is performed as many periods as desired (S143). In 5143, if it is determined that deposition is not performed as many periods as desired, the In(Ga)As material layer 241 and the InAl(Ga)As material layer 242 are alternately deposited again until the desired number of deposition periods is reached.

Here, the In(Ga)As material layer 241 and the InAl(Ga)As material layer 242 are deposited by one of metallic organic chemical vapor deposition (MOCVD), molecular beam epixaxy (MBE), and chemical beam epitaxy (CBE). In alternating deposition, the In(Ga)As material layer 241 and the InAl(Ga)As material layer 242 are each formed to a thickness of 1 to 10 monolayers, and are alternately deposited to 10 to 100 periods. In FIG. 2C, parts of the alternating deposition periods of the In(Ga)As material layer 241 and the InAl(Ga)As material layer 242 are omitted for simplification.

Meanwhile, when it is determined that the deposition is performed as many periods as desired, the next step (S144) is processed, which is described with reference to FIG. 2D. In FIG. 2D, the alternately deposited In(Ga)As and InAl(Ga)As material layers 241 and 242 simultaneously use self-assembly caused by lattice-mismatch between the In(Ga)As material layer 241 and the InAl(Ga)As material layer 242, and phase separation by the In(Ga)As material layer 241 and the InAl(Ga)As material layer 242. The self-assembly is caused by strain energy accumulated due to lattice-mismatch between the In(Ga)As material layer 241 and the InAl(Ga)As material layer 242, thereby forming an initial In(Ga, Al)As quantum dot. After the initial In(Ga, Al)As quantum dot is formed, the phase separation is caused by growth behavior of the group 3 elements around the initial In(Ga, Al)As quantum dot, and affects the initial En(Ga, Al)As quantum dot. In other words, the initial In(Ga, Al)As quantum dot is affected by the phase separation that occurs due to different growth behavior of a material itself, such as diffusion distance and velocity of the group 3 elements (i.e. In, Ga, Al), and is formed into a terminal In(Ga, Al)As quantum dot 245.

Referring to FIGS. 1A and 2E, after formation of the quantum dot 245, a second lattice-matched layer 231 is formed on the active layer 240 (S150). The second lattice-matched layer 231 is almost the same as the first lattice-matched layer 230 in function and thus will not be described in detail (refer to above description of first lattice-matched layer 230).

Referring to FIGS. 1A and 2F, a second clad layer 250 is formed on the second lattice-matched layer 231 (S160). The second clad layer 250 may be formed of p-(n-)InAl(Ga)As or p-(n-)In(Ga, As)P. The second clad layer 250 is formed with a different conductivity type from the first clad layer 220. That is, when the first clad layer 220 is n-InAl(Ga)As, the second clad layer 250 is p-InAl(Ga)As. Referring to FIGS. 1A and 2G, an ohmic contact layer 260 that can control ohmic contact is formed on the second clad layer 250 (S170).

When a voltage is applied to each of the substrate 210 and the ohmic contact layer 260 of the quantum laser diode 200 fabricated by the above-described process, a hole injected through the ohmic contact layer 260 and an electron injected through the substrate 210 travel around the quantum dot 245 in the active layer 240 and are recombined. Thereby, the quantum dot laser diode 200 fabricated by the above-described process may emit a specific wavelength of laser light.

FIG. 3A is a tunneling electron microscope (TEM) photograph of a cross-section of an exemplary embodiment of a quantum dot specimen (QD1) formed by the above-described process, and FIG. 3B is a TEM photograph of a cross-section of an exemplary embodiment of a quantum dot specimen (QD2) formed according to conventional art. The present invention is compared with the conventional art with reference to FIGS. 3A and 3B.

As shown in FIG. 3B, a conventional quantum dot 320 has a relatively smaller height than width. For example, the conventional quantum dot 320 has an aspect ratio (ratio of height to width) of about 0.1. On the other hand, a quantum dot according to the present invention 310 has a significantly larger aspect ratio of about 0.25. The larger the aspect ratio, the more circular or symmetrical the quantum dot. Accordingly, the quantum dot 310 of the present invention has an oval shape and good symmetry compared to the conventional quantum dot 320. In deed, the quantum dot 310 of the present invention has a relatively ideal form. As a result, using the ideal quantum dot 310 as an active layer may improve device's characteristics.

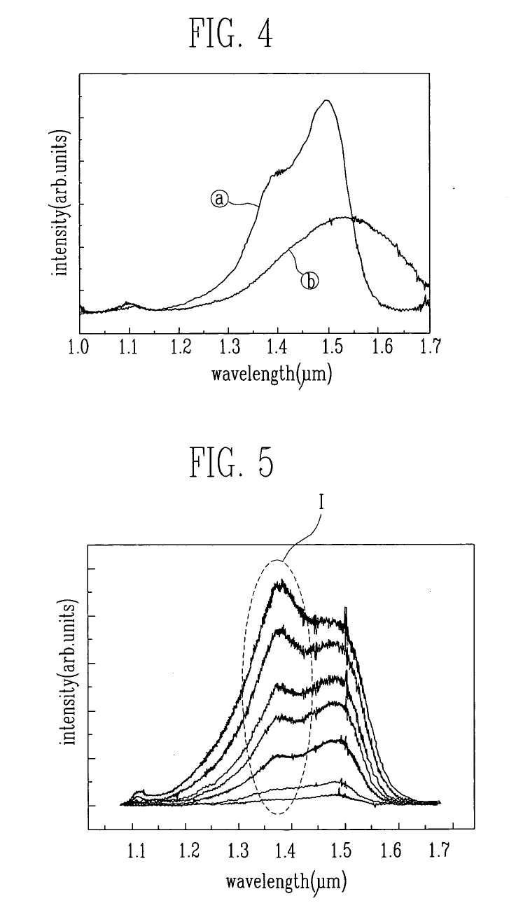

FIG. 4 shows a graph \textcircled{a} illustrating room-temperature photoluminescence characteristics of a quantum dot specimen (QD1) produced according to the present invention, and a graph \textcircled{b} illustrating room-temperature photoluminescence characteristics of a quantum dot specimen (QD2) produced according to conventional art. Referring to FIG. 4, the horizontal axis indicates wavelength while the vertical axis indicates intensity (arbitrary units). FIG. 4 shows photoluminescence (PL) peaks of the QD2 formed by a quantum dot forming method using conventional self-assembly, and of the QD1 formed by a quantum dot forming method using an alternate growth method of the present invention. As shown in FIG. 4, since the quantum dot specimen (QD1, \textcircled{a}) formed according to the present invention has excellent uniformity compared to the quantum dot specimen (QD2, \textcircled{b}) formed according to conventional art, it can be seen that a full-width at half maximum (FWHM) of its PL peak is significantly reduced and an intensity of its PL peak is greatly enhanced.

FIG. 5 shows a graph illustrating PL characteristics at room temperature according to excitement intensity of a quantum dot specimen produced by the present invention as a function of wavelength. Referring to FIG. 5, the horizontal axis indicates wavelength while the vertical axis indicates intensity. As seen from the graph of FIG. 5, as intensity (arbitrary units) increases, intensity of the PL peak at a short wavelength part increases gradually and becomes greater than at a long wavelength part. From this phenomenon, it can be noted that the PL peak at the short wavelength part is affected by a first excited level (I), and a good quantum dot can be formed by the present invention. In other words, it may be noted that when the PL peak caused by the first excited level (I) is indicated easily, an ideal form of quantum dot is formed.

Although exemplary embodiments of the present invention disclosed herein concern a laser diode using a quantum dot layer formed by alternately depositing an In(Ga)As material layer and an InAl(Ga)As material layer as an active layer, a laser diode using a quantum dot layer formed by alternately depositing an In(Ga)As material layer and an In(Ga, Al, As)P material layer as an active layer may be also fabricated by the above-described processes. Such a quantum dot laser diode can also provide the same effects and characteristics as the above-described exemplary embodiments. In addition, although, in the exemplary embodiments, partial stacking periods of the quantum dots are omitted for convenience of description, the stacking periods may be selected as desired.

Moreover, in the exemplary embodiments, a laser diode may be fabricated using a quantum dot layer comprising quantum dots having multiple stacking periods. However, a laser diode may be also fabricated by stacking a plurality of quantum dot layers comprising quantum dots having multiple stacking periods. When quantum dot layers are multiply stacked, barrier layers (such as a hetero-junction structure layer) are formed between the quantum dot layers.

In the above disclosure, materials enclosed in parentheses are optionally included. Thus, for example, an In(Ga)As layer may be an InAs layer or an InGaAs layer.

As described above, an ideal form of quantum dot is formed simultaneously using a self-assembly method caused by lattice-mismatch and an alternate growth method, and used as an active layer of a quantum dot laser diode. Consequently, quantum dot uniformity is good, an FWHM of a PL peak is narrow, and intensity of the PL peak is significantly increased. Thus, performance of the quantum dot laser diode is remarkably improved.

While the present invention has been shown and described with reference to certain exemplary embodiments thereof, it will be understood by those skilled in the art that various changes in form and details may be made therein without departing from the spirit and scope of the present invention as defined by the appended claims.

1. A quantum dot laser diode, comprising:
a first clad layer formed on an InP substrate;
a first lattice-matched layer formed on the first clad layer;
an active layer formed on the first lattice-matched layer, the active layer comprising a plurality of layers of InAlAs quantum dots in the each of which is formed by an alternate growth method which uses alternating deposition of In(Ga)As material layer and In(Ga,Al,As)P material layer;
a second lattice-matched layer formed on the active layer;
a second clad layer formed on the second lattice-matched layer; and
an ohmic contact layer formed on the second clad layer.

2. The quantum dot laser diode according to claim 1, wherein a barrier layer is the first lattice-matched layer which is formed on the active layer.

3. The quantum dot laser diode according to claim 2, wherein the In(Ga, Al)As quantum dot is formed by alternately depositing an In(Ga)As material layer and an InAl(Ga)As material layer in sequence, which are relatively more lattice-mismatched.

4. The quantum dot laser diode according to claim 1, wherein the plurality of InGaPAs quantum dots is formed by alternately depositing an In(Ga)As material layer and an In(Ga, Al, As)P material layer in sequence.

5. The quantum dot laser diode according to claim 3, wherein the In(Ga)As and InAl(Ga)As material layers, which are used in alternating deposition, each have a thickness ranging from 1 to 10 monolayers.

6. The quantum dot laser diode according to claim 4, wherein the In(Ga)As and In(Ga, Al, As)P material layers, which are used in alternating deposition, each have a thickness ranging from 1 to 10 monolayers.

7. The quantum dot laser diode according to claim 3, wherein the In(Ga)As and InAl(Ga)As material layers, which are used in alternating deposition, are alternately deposited to 10 to 100 periods.

8. The quantum dot laser diode according to claim 4, wherein the In(Ga)As, and In(Ga, Al, As)P material layers, which are used in alternating deposition, are alternately deposited to 10 to 100 periods.

9. The quantum dot laser diode according to claim 2, wherein the first lattice-matched layer, and the second lattice-matched layer consist of InAl(Ga)As, In(Ga, Al, As)P, or a combination thereof, and are formed in a separate confinement hetero-junction (SCH) structure.

10. The quantum dot laser diode according to claim 9, wherein the SCH structure has a waveguide formed in a Step index (SPIN) structure.

11. The quantum dot laser diode according to claim 10, wherein a quantum well is inserted into the SPIN SCH structure.

12. The quantum dot laser diode according to claim 9, wherein the SCH structure has a waveguide formed in a Graded Index (GRIN) structure.

13. The quantum dot laser diode according to claim 12, wherein a quantum well is inserted into the GRIN SCH structure.

14. A method of fabricating a quantum dot laser diode, comprising the steps of:
forming a first clad layer on an InP substrate;
forming a first lattice-matched layer on the first clad layer;
forming an active layer on the first lattice-matched layer, the active layer including at least one quantum dot layer formed of an In(Ga, Al)As quantum dot and an In(Ga, Al, P)As quantum dot grown by an alternating deposition method;
forming a second lattice-matched layer on the active layer;
forming a second clad layer on the second lattice-matched layer, and
forming an ohmic contact layer on the second clad layer.

15. The method according to claim 14, wherein in the step of forming the active layer, when a plurality of quantum dot layers are stacked, further comprising the step of forming a barrier layer between the quantum dot layers.

16. The method according to claim 15, wherein the In(Ga, Al)As quantum dot is formed by alternately depositing an In(Ga)As material layer and an InAl(Ga)As material layer in sequence, which are relatively more lattice-mismatched.

17. The method according to claim 15, wherein the In(Ga, Al, P)As quantum dot is formed by alternately depositing an In(Ga)As material layer and an In(Ga, Al, As)P material layer in sequence, which are relatively more lattice-mismatched.

18. The method according to claim 16, wherein the alternating deposition is performed by one of metallic organic chemical vapor deposition (MOCVD), molecular beam epitaxy (MBE), and chemical beam epitaxy (CBE).

19. The method according to claim 17, wherein the alternating deposition is performed by one of metallic organic chemical vapor deposition (MOCVD), molecular beam epitaxy (MBE), and chemical beam epitaxy (CBE).

20. The quantum dot laser diode according to claim 1, wherein the plurality of in AlAs quantum dots is formed by alternately depositing an In(Ga)As material layer and an InAl(Ga)As material layer in sequence.
